(19) United States
(12) Patent Application Publication
(10) Pub. No.: US 2004/0178426 A1
(43) Pub. Date: Sep. 16, 2004

(54) Laminated semiconductor radiation detector

(76) Inventors: Leonid Melekhov, Kiryat Ekron (IL); Eliezer Shtekel, Kiryat Arba (IL); Benjamin Joshua Reisman, Halamish (IL); Michael Factor, Ofra (IL)

Correspondence Address: SQUIRE, SANDERS & DEMPSEY L.L.P, 600 HANSEN WAY, PALO ALTO, CA, 94304-1043, US

(21) Appl. No.: 10/739,816

(22) Filed: Dec. 17, 2003

Related U.S. Application Data
(63) Continuation-in-part of application No. PCT/IL02/00471, filed on Jun. 17, 2002.

(30) Foreign Application Priority Data
Jun. 19, 2001 (IL) 143852

(51) Int. Cl. H01L 27/148

(52) U.S. Cl. 257/233

(57) ABSTRACT

A detection system which includes at least one element enabling the detection of high-energy radiation. The element has a multilayered structure including a lower electrode, a first layer including a semiconducting dark current effects reducing substance deposited on the lower electrode, a second layer including a wide band gap semiconducting substance deposited onto the first layer, and an upper electrode deposited onto the second layer. In other embodiments, the positioning of the first and second layers is reversed.

The present application is a continuation-in-part of and claims priority to international application PCT/IL/02/00471, filed 17 Jun. 2002, established under PCT Article 21(2) in English, which claims priority to Israeli patent application Serial No. 143852, filed 19 Jun. 2001 which applications are incorporated by reference herein.

### FIELD OF THE INVENTION

The present invention relates to improved X-ray detectors and imagers having reduced dark current effects and increased sensitivity to dark current ratios, and methods of manufacturing thereof.

### BACKGROUND OF THE INVENTION

X-ray and gamma ray detection is useful in a wide variety of scientific and technical endeavours. These include medical imaging applications such as X-ray radiography, X-ray computed tomography (CT), single photon emission computed tomography (SPECT) and positron emission tomography (PET). Other applications of note are non-destructive testing and quality control of manufacturing components, baggage inspection systems such as those installed at customs, and astrophysics and astronomy applications such as galactic surveys, and space exploration.

Special photographic plates can be used for X-ray detection. However, for repeated use and for maximum data collection, semiconductor detectors exhibiting the well-known photoelectric effect, whereby incident photons of radiation generate charge carriers for subsequent detection and monitoring, offer many advantages. A major advantage of semiconductor detectors is that the electronic signals generated can be readily processed to produce numerical data, for digital image processing and the like.

For the room temperature detection of high-energy electromagnetic radiation, candidate materials are mercuric iodide (HgI₂), cadmium telluride (CdTe), cadmium zinc telluride (CdZnTe) and lead iodide (PbI₂), having wide band gaps of 2.2 eV, 1.45 eV, 1.5 eV and 2.6 eV, respectively. Electrodes are applied to both sides of the wide band gap semi-conducting substance, and a potential difference is maintained between the electrodes. Bombardment by high-energy photons, such as X-rays and gamma rays, results in the formation of hole-electron pairs, which causes current flow between the electrodes. This electrical signal is used for detection purposes, its intensity being related to the intensity of radiation incident on the wide band gap semiconducting substance.

When using the term high-energy radiation, radiation in the range of from about 6 KeV to several MeV is intended. For most X-ray detecting applications, detection of radiation in the range of from about 15 KeV to about 500 KeV is used.

For mapping purposes, such as medical diagnostic applications, large detectors are preferred. One or both electrodes may be divided into a pixel array, each pixel detecting radiation in its vicinity.

To provide uniform properties across the surface of the wide band gap semiconducting substance, plates cut and polished from single crystals have traditionally been used. However, these crystals are expensive and time consuming to grow and only limited sizes have been achieved.

Mercuric iodide (HgI₂) and lead iodide (PbI₂) have significantly higher atomic weights and thus better X-ray stopping power than cadmium telluride (CdTe) and cadmium zinc telluride (CdZnTe). Since the dominant charge carriers in HgI₂ are electrons and not holes, as is the case with PbI₂, it is possible to construct detectors comprising thicker layers of HgI₂ than of PbI₂. For the aforementioned reasons, HgI₂ is the preferred material for use in X-ray detectors and X-ray imagers.

To overcome the inherent size limitations of single crystals and their high cost, the use of polycrystalline, coherent, continuous films has been disclosed in U.S. Pat. No. 5,892,227, the contents of which are incorporated herein by reference. U.S. Pat. No. 5,892,227 describes methods for producing plates from wide band semiconductors by various techniques, including hot pressing and sintering of an ultra-fine powder, mixing the powdered material with a matrix to form a composite material for subsequent painting onto an appropriate substrate, and by sublimation and subsequent condensation on a cooled substrate, which is essentially a PVD technology.

Numerous publications describe polycrystalline HgI₂ detectors and imagers as are well known to persons in the art.

An improved, powder in matrix composite comprising HgI₂ particles in an organic matrix, such as polystyrene, acrylic or vinylic polymers, and methods for manufacturing films therefrom such as doctor-blade, die-pressing and screen-printing, has been described in co-pending Israel Patent Application Number 141,483 assigned to the applicant and incorporated herein by reference. The flexibility of the concept, ease of manufacture, low capital outlay for manufacturing equipment and the large area films obtainable, make HgI₂ detectors manufactured in this manner very attractive. However, their sensitivities are less than those of PVD deposited and single crystal HgI₂ detectors.

Despite the above mentioned and other advantages of HgI₂ for high energy radiation detectors and imagers, HgI₂ has the disadvantage that the material is not compatible with aluminium and copper bus lines and the like, often used for TFT electronics in preferred substrates.

A further disadvantage associated with using HgI₂ layers for detectors and imagers is that HgI₂ has a relatively large dark current signal. Even when not irradiated by high-energy radiation, random occurrences, associated with the absolute temperature of the material, for example, give rise to the generation of electron-hole pairs. This generates spurious signals or ‘noise’, which, because of its random nature, and thus non-uniformity across the pixel array, may adversely affect image clarity and contrast in images generated by pixilated array imagers.

In general, single crystal detectors have the best sensitivity and also the lowest dark current effects, since dark current is associated with random movement of charge carriers and with vacancies, grain boundaries and so on. Single crystals are, however, expensive to produce and are limited in size.

The present invention addresses the disadvantages described above.

### SUMMARY OF THE INVENTION

It is an object of the present invention to improve the high-energy radiation detection signal to dark current noise ratio of high-energy radiation detectors and imagers by minimizing the dark current therefrom without significantly adversely affecting the intensity of the high-energy radiation detection signal.

It is a further object of the present invention, when a detector layer comprises a corrosive wide band gap semiconductor species such as HgI₂, to provide a thick protective layer between the detector layer and reactive metallic components on pixel arrays such as aluminium bus lines and the like.

It is a further object of the present invention to provide good adhesion between the disparate materials used for the wide band gap detector layer, and the selected substrate used for supporting the pixilated array, and to provide mechanical stability and ruggedness to the probe device.

These and other objects of the present invention will be clear from the following description of the invention and its various embodiments.

The present invention relates to improved X-ray detectors and imagers, having reduced dark current effects and thus increased sensitivity to dark current ratios, and methods of manufacturing thereof. More particularly, but not exclusively, the invention relates to multilayer wide band gap semiconductors which include an upper electrode layer attached to a continuous wide band gap polycrystalline semiconductor upper layer over a composite layer including wide band gap semiconductor particles in a polymer matrix. A lower electrode layer, preferably a pixel array on a suitable substrate, is attached thereto. The invention also discloses manufacturing processes suitable for assembly of such multilayer sandwich constructions.

According to a first aspect of the present invention, there is provided a detection and imaging system which includes at least one element enabling the detection of radiation, the element having a multilayered structure including a lower electrode, a continuous first layer of a semiconducting dark current effects reducing substance deposited thereon, a continuous second layer of a wide band gap semiconducting substance deposited onto the first layer, and an upper electrode deposited onto the second layer.

The continuous first layer of the semiconducting dark current effects reducing substance is between 10 microns and 400 microns thick, and the continuous second layer of the wide band gap semiconducting substance is between 50 microns and 1000 microns thick. The continuous first layer of the semiconducting dark current effects reducing substance is preferably between 40 microns and 200 microns thick, and the continuous second layer of the wide band gap semiconducting substance is preferably between 100 microns and 400 microns thick.

The dark current effects reducing substance preferably comprises a particle in matrix composite where: (a) the particles are selected from the group consisting of cadmium zinc telluride, cadmium telluride, lead iodide, mercury iodide, bismuth iodide, thallium bromide and mixtures thereof, and where (b) the matrix material is selected from the group consisting of aliphatic and aromatic homopolymers and copolymers. Preferably, at least 90% of the particles in the particle in matrix composite have sizes in the range of 1 micron to 50 microns.

Preferably, the wide band gap semiconducting substance is a polycrystalline film deposited by vapour deposition, which is preferably physical vapor deposition, but could be chemical vapor deposition.

Preferably, the wide band gap semiconducting substance includes HgI₂ and the electrodes include a material and topography and are deposited by a deposition technique, such that: (a) the material is selected from the group consisting of indium-tin oxide, Au, Ni, Pt, Pd, Cr, Ge, Si and C; (b) the topography is selected from the group consisting of a continuous layer, a flat panel TFT array structure, a CCD structure and a CMOS structure; and (c) the deposition technique is selected from the group consisting of painting, spraying, sputtering, vacuum deposition and screen-printing. The detection and imaging system preferably may detect electromagnetic radiation in the range of from about 6 KeV to several MeV.

According to another aspect of the present invention, there is provided a multilayered structure which includes a lower electrode, a continuous first layer of a semiconducting dark current effects reducing substance deposited thereon, a continuous second layer of a wide band gap semiconducting substance deposited onto the first layer, and an upper electrode deposited onto the second layer.

The continuous first layer of the semiconducting dark current effects reducing substance is between 10 microns and 400 microns thick, and the continuous second layer of the wide band gap semiconducting substance is between 50 microns and 1000 microns thick. Preferably, the continuous first layer of the semiconducting dark current effects reducing substance is between 40 microns and 200 microns thick, and the continuous second layer of the wide band gap semiconducting substance is preferably between 100 microns and 400 microns thick.

Optionally, the dark current effects reducing substance includes a particle in matrix composite where: (a) the particles are selected from the group consisting of cadmium zinc telluride, cadmium telluride, lead iodide, mercury iodide, bismuth iodide, thallium bromide and mixtures thereof; and

(b) the matrix material is selected from the group consisting of homopolymers and copolymers of aliphatic and aromatic monomers containing one or more ethylenic bonds.

Optionally, at least 90% of the particles in the particle in matrix composite have sizes in the range of 1 micron to 50 microns, and the wide band gap semiconducting substance is a polycrystalline film deposited by vapour deposition, which is optionally physical vapour deposition.

Preferably, the electrodes include a material and topography and are deposited by a deposition technique, such that: the material is selected from the group consisting of indium-tin oxide, Au, Ni, Pt, Pd, Cr, Ge, Si and C; the topography is selected from the group consisting of a continuous layer, a flat panel TFT array structure, a CCD structure and a CMOS structure; and the deposition technique is selected from the group consisting of painting, spraying, sputtering, vacuum deposition and screen-printing.

In another embodiment, the order of the semiconducting dark currents reducing substance layer and the continuous layer of a wide band semiconductor may be reversed when constructing the radiation detection elements and multilayers of the present invention. The semiconducting dark currents reducing substance would be near the pixelated substrate/electrode while the continuous layer of a wide band semiconductor would be near a second electrode. The remainder of the construction, materials, composition and methods would be similar to the embodiments described previously. When the semiconducting dark currents reducing substance layer and the substrate are thus separated by the wide band semiconductor layer, the semiconducting dark currents reducing substance layer may range from about 10 microns to about 1000 microns, preferably between about 40 microns to about 400 microns.

### BRIEF DESCRIPTION OF THE DRAWINGS

For a better understanding of the invention and to show how the same may be carried into effect, reference will now be made, purely by way of example, to the accompanying drawings.

With reference to the drawings, it is stressed that the particulars shown are by way of example and for purposes of illustrative discussion of the preferred embodiments of the present invention only, and are presented in the cause of providing what is believed to be the most useful and readily understood description of the principles and conceptual aspects of the invention. In this regard, no attempt is made to show structural details of the invention in more detail than is necessary for a fundamental understanding of the invention, the description taken with the drawings making apparent to those skilled in the art how the several forms of the invention may be embodied in practice. In the accompanying drawings:

FIG. 1 is a schematic representation of a prior art multilayer polycrystalline high-energy radiation detector, showing the various layers from which it is constructed;

FIG. 2 is a schematic representation of a multilayer composite high-energy radiation detector, showing the various layers from which it is constructed;

FIG. 3 is a schematic representation of a generalized embodiment of an improved high-energy radiation detector in accordance with the present invention, showing the various layers from which it is constructed; and

FIG. 4 is a graph showing the X-ray detection signal/dark current ratio vs. applied bias response of a detector including a polycrystalline HgI₂ layer produced by PVD, of a detector including a composite HgI₂ particles in polystyrene matrix layer produced by screen-printing, and of a detector including a double layer comprising a polycrystalline HgI₂ layer produced by PVD adhered to a composite HgI₂ particles in polystyrene matrix layer produced by screen-printing.

### DESCRIPTION OF THE PREFERRED EMBODIMENTS

Before explaining the invention in further detail, it is to be understood that the invention is not limited in its application to the details of construction and the arrangement of the components set forth in the following description or illustrated in the accompanying drawings. The invention is applicable to other embodiments or of being practiced or carried out in various ways. Also, it is to be understood that the phraseology and terminology employed herein is for the purpose of description and should not be regarded as limiting.

It is appreciated that certain features of the invention, which are, for clarity, described in the context of separate embodiments, may also be provided in combination in a single embodiment. Conversely, various features of the invention that, for brevity, are described in the context of a single embodiment, may also be provided separately or in any suitable sub-combination.

Reference is now made to FIG. 1, which is a schematic representation of a typical prior art high-energy radiation detector 10, showing the various layers from which it is constructed. Beginning with the bottom layer and moving upwards in FIG. 1, the typical prior art high-energy radiation detector 10 comprises a substrate 12 supporting a pixel array 13, a tie-layer 14, a polycrystalline, wide band gap semiconductor layer 17, an upper electrode 18, to which a high voltage Pt wire 22 may be attached by a suitable adhesive 20. Typical prior art high-energy radiation detector 10 comprises a flat panel substrate 12 having metallic pixels 13 deposited thereon, which function as the bottom electrode of detector 10. Often the bottom electrode is formed from indium-tin oxide (ITO) or other non-metal, conductive materials. The bottom pixel array 13 is coated with a tie-layer 14, such as Humiseal® 1B12, which is a commercially available polyacrylic, polyvinylic mixture in a mixed methyl ethyl ketone/toluene solvent. The tie-layer 14 acts as an adhesive and prevents the wide band gap semiconductor 17 from peeling off the bottom pixel electrodes. The tie-layer 14 is usually less than 0.5 micron and is generally applied by dipping the substrate into a dilute solution of the adhesive from which the solvent is then allowed to evaporate. Alternatively, the tie-layer 14 may be painted onto the upper surface of the bottom pixel array 13. A polycrystalline film 17 of a wide band gap semiconductor material is fixed to the bottom pixel array 13 by the tie-layer 14. The polycrystalline film 17 of a wide band gap semiconductor material may be a polycrystalline film made by sintering a powder compact or, for example, by chemical or physical vapor deposition. Polycrystalline film 17 fabricated by vapor deposition techniques, such as physical vapor deposition and chemical vapor deposition, may be deposited directly onto the pixilated 13 substrate 12, in which case tie-layer 14 is redundant. Alternatively, polycrystalline film 17 fabricated by vapor deposition techniques or by sintering, may be manufactured separately and then retrofitted onto the pixilated 13 substrate 12, using a tie-layer 14 comprising a suitable adhesive.

A continuous upper electrode 18 is deposited onto the surface of the wide band gap semiconductor polycrystalline film 17 that is distal from the substrate 12. This upper electrode 18 may be deposited by any of a variety of suitable processes including, for example, vacuum deposition, printing or spray-painting. A high voltage platinum bias wire 22 may be attached to the upper electrode 18 using conductive glue 20, of which several alternatives are readily available commercially.

The wide band gap semiconductor polycrystalline film 17 acts as a photoconducting semiconductor in the generalized prior art high-energy radiation detector 10 illustrated in FIG. 1. The wide band gap semiconductor polycrystalline film 17 is placed directly onto the tie-layer 14 coated pixel array 13. The pixel array 13 may be a pixel readout flat panel (FP) TFT array, a charge coupled device (CCD) or a complementary metal oxide semiconductor (CMOS) array, for example. Such pixel arrays are commercially available and come printed onto suitable substrates 12. Typical FP TFT or CCD substrates used for detector 10 contain square pixels having a conductive coating, the latter serving as the bottom pixel electrodes for the detector. The pixels are typically about 100×100 microns and each pixel is separated from its nearest neighbours in all directions by about 10-15 microns.

Optionally and preferably, the complete prior art high-energy radiation detector 10 may be mechanically encapsulated with Parylene, Humiseal® 1B12, or a similar insulating, inert material (not shown), and connected to a pixel array readout unit. The readout electronics unit may be connected to a PC and the images acquired may then be evaluated with image viewing and acquisition software.

The generalized prior art high-energy radiation detector 10 illustrated in FIG. 1 however, typically has a poor signal to noise ratio due to high dark current effects. The high dark current effects are an unfortunate occurrence with polycrystalline wide band gap semiconducting materials and are caused by the high concentration of grain boundaries and other defects in the wide band gap semiconductor polycrystalline film 17.

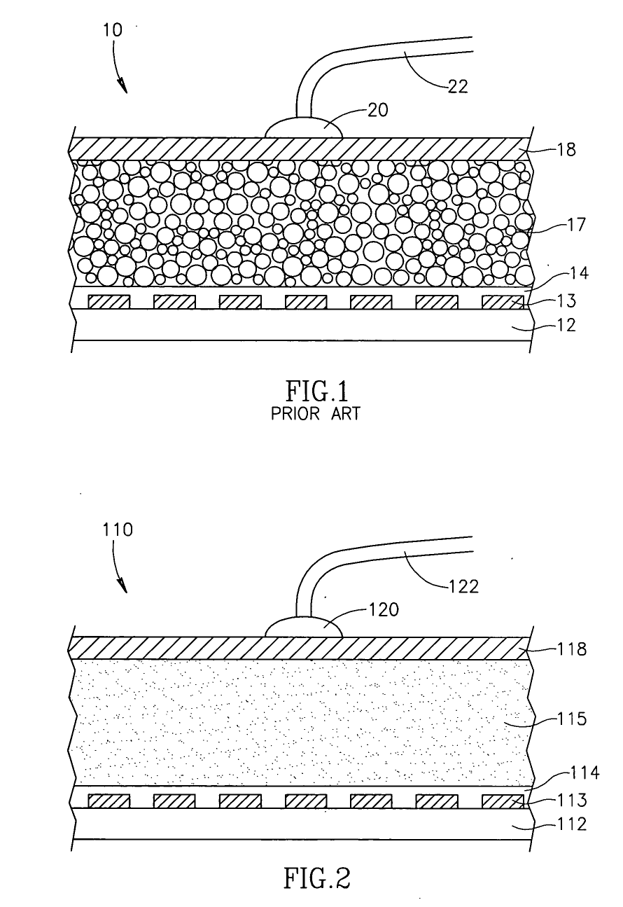

Reference is now made to FIG. 2, which is a schematic representation of a composite high-energy radiation detector 110, showing the various layers from which it is constructed. Beginning with the bottom layer and moving upwards in FIG. 2, the composite prior art high-energy radiation detector 110 comprises a substrate 112 supporting a pixel array 113, a tie-layer 114, a particle-matrix composite layer comprising wide band gap semiconductor particles in a polymer matrix 115, an upper electrode 118, to which a high voltage Pt wire 122 may be attached by a suitable adhesive 120.

The substrate 112, pixel array 113, tie-layer 114, upper electrode 118, suitable adhesive 120 and high voltage Pt wire 122 of the composite high-energy radiation detector 110 shown in FIG. 2, is similar to the substrate 12, pixel array 13, tie-layer 14, upper electrode 18, suitable adhesive 20 and high voltage Pt wire 22 of the prior art, high-energy radiation detector 10 shown in FIG. 1, mutatis mutandis.

However, the film that enables the detection of high-energy radiation in the composite high-energy radiation detector 110 shown in FIG. 2 comprises a particle-matrix composite layer comprising wide band gap semiconductor particles in a polymer matrix 115. Such particle-matrix composites comprising HgI₂ particles in various organic matrices, such as polystyrene, acrylics and vinyl polymers, may be deposited from a colloidal suspension of the particles in a solution comprising, for example, 1 part polystyrene in 3 parts toluene by weight; they may be easily processed, for example, by being coated as a liquid film onto a chosen substrate. Mercuric iodide has very good X-ray detecting properties, and polystyrene is a well-understood polymeric matrix material that offers easy fabrication. Polystyrene may be dissolved in methyl benzene (toluene) and, by varying the average molecular weight of the polymer molecules, the quantity of solvent and other additives, the particle to matrix ratio and the particle size, both the mechanical and photo-detecting properties of the dry film, and the surface tension, viscosity, rheology and density of the colloidal dispersion may be tailored for ease of fabrication and desired properties of the product.

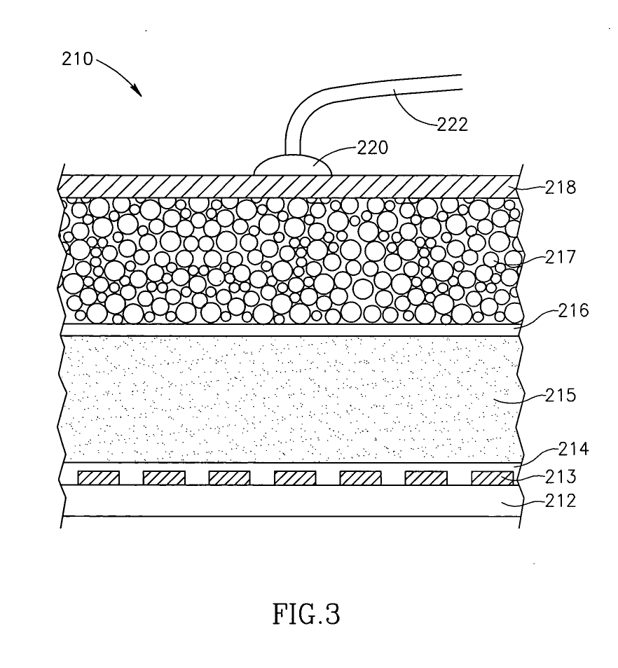

In a preferred embodiment of the present invention shown in FIG. 3, to which reference is now made, a high-energy radiation detector 210 is illustrated. Detector 210 is comprised of the following layers when moving from the bottom layer in FIG. 3 upward: a substrate 212 supporting a pixel array 213, a first tie-layer 214, a semiconducting dark current effects reducing substance layer 215, a second tie-layer 216, a wide band gap semiconductor polycrystalline layer 217, and an upper electrode 218. A high voltage Pt wire 222 is attached with a suitable conductive adhesive 220 to upper electrode 218.

The dark current effects reducing substance layer 215 is typically a composite wide band gap semiconductor layer, where the semiconducting particles are dispersed in a polymer matrix. Therefore, when discussing FIG. 3, the semiconducting dark current effects reducing substance layer 215 will herein often be denoted as a composite wide band gap semiconductor layer 215 and used interchangeably, without any intent at being limiting.

The wide band gap semiconductor polycrystalline layer 217 may include any of many different suitable wide band gap semiconductor polycrystalline materials. Typically, it may comprise a mercuric iodide (HgI₂) thin film, the latter produced by physical vapor deposition (PVD). Other deposition techniques such as chemical vapor deposition (CVD) may also be used for fabricating wide band gap semiconducting polycrystalline layer 217.

There are a wide variety of candidate materials for tie-layers 214 and 216, such as Humiseal® 1B12, a commercially available polyacrylic, polyvinyl mixture in a mixed methyl ethyl ketone/toluene solvent.

Suitable substrates for pixilated 213 substrate 212 include flat panel TFT arrays on amorphous silicon, such as those available from dpiX LLC.

Tie-layer 214 may not be a conductive adhesive as this may short pixels 213. However, tie-layer 216 may comprise a semiconducting material such as a dispersion of semiconducting particles within a polymeric matrix, which may further lower the dark current response.

If the composite wide band gap semiconductor layer 215 is liquid coated directly onto pixilated 213 substrate 212, and if the matrix material in the composite wide band gap semiconductor layer 215 adheres well to pixels in the pixilated 213 substrate 212, and without adverse chemical reaction between adjacent materials, tie-layer 214 may be superfluous.

The general requirements of the composite wide band gap semiconductor material in a polymer matrix layer 215 and the optional tie-layers 214 and 216 are such that they have an appropriate thickness to effectively distance the wide band gap semiconductor polycrystalline layer 217 from the electrode pixel array 213 and circuitry deposited onto substrate 212, and that they are suitably insulating. However, the dark current effects reducing substance layer 215 and the optional tie-layers 214 and 216 must allow holes and electrons to pass through to the electrodes. The dark current effects reducing substance layer 215 and the optional tie-layers 214 and 216 are preferentially required to have substantially uniform through-thickness electronic properties across their areas so that they do not distort the signal produced by the wide band gap semiconductor polycrystalline layer 217. Finally, as with all extensive, multilayer constructions of disparate materials, there is a requirement to restrict thermal expansion stresses and strains to acceptable levels, thus preventing delamination. Restriction of thermal expansion stresses and strains can be achieved either by matching the expansion coefficients of the various materials or by using polymeric materials that can undergo significant strain without loss of integrity.

Composite layers comprising wide band gap semiconductor particles in a polymer matrix layer 215 overcome both the thermal expansion stresses between the substrate 212 and the polymer matrix layer 215, and the thermal expansion stresses between the composite wide band gap semiconductor particles in polymer matrix layer 215 and the wide band gap semiconductor polycrystalline layer 217. This is the result of the lower stiffness and greater plasticity of the polymer matrix.

Particle size is preferably restricted to ensure that the dark current effects reducing substance layer 215 has substantially uniform through-thickness electronic properties across its area such that the signal produced by the wide band gap semiconductor polycrystalline layer 217 is not distorted thereby.

Typically, composite wide band gap semiconductor layer 215 comprises 60% semiconductor particles by volume. The particle size is generally less than 100 microns in size, and preferably less than 10 microns in size. More preferably, 90% of the particles are in the range of from 1 to 5 microns in size. In general, the composite wide band gap semiconductor layer 215 may contain up to 70% semiconductor particles by volume.

It will be appreciated that the particle material used in the composite wide band gap semiconductor material in a polymer matrix layer 215 may comprise any of a wide range of wide band gap semiconductor materials and mixtures thereof, and may be selected from any of the wide band gap semiconductors from which the wide band gap semiconductor layer of detectors/imagers are sometimes comprised. Suitable materials include lead iodide (PbI₂) bismuth iodide (BiI₃), thallium bromide (TlBr), mercuric iodide (HgI₂) cadmium telluride (CdTe), cadmium zinc telluride (CdZnTe) and mixtures thereof, for example.

It will be further appreciated that a very wide range of polymers are suitable candidates for the matrix material, including, but not limited to, polystyrene, acrylics and vinyl polymers.

Preferably, the polymer matrix of the composite wide band gap semiconductor material in a polymer matrix layer 215 will have good adhesion to both substrate 212 and to the wide band gap semiconductor polycrystalline layer 217. In order to achieve this, the aforementioned polymer matrix may be softened, by heating, or by use of an appropriate solvent, for example.

It will, however, be appreciated that the preferred thickness and tolerances for the composite wide band gap semiconductor particles in polymer matrix layers depend critically on the type of wide band gap semiconductor polycrystalline layer selected, the choice of which, in turn, depends on the application and financial considerations. The preferred thickness may also depend on the energy of the photons to be detected, operating temperatures and the like. For the abovementioned reasons, thickness dimensions for the present invention have not been included, but the underlying science is well understood by one skilled in the art, and optimization for particular applications is achievable without undue experimentation.

In prototype detectors and imagers, indium-tin oxide was used for the bottom electrode and gold was used for the upper electrode. Many noble metals and other electrode materials that do not react with HgI₂ may be used instead, such as Ni, Pt, Pd, Cr, Ge, Si or C. A suspension of electrode material may be painted on. Alternatively, electrodes may be sputtered on, vacuum deposited, sprayed on, or screen-printed, for example.

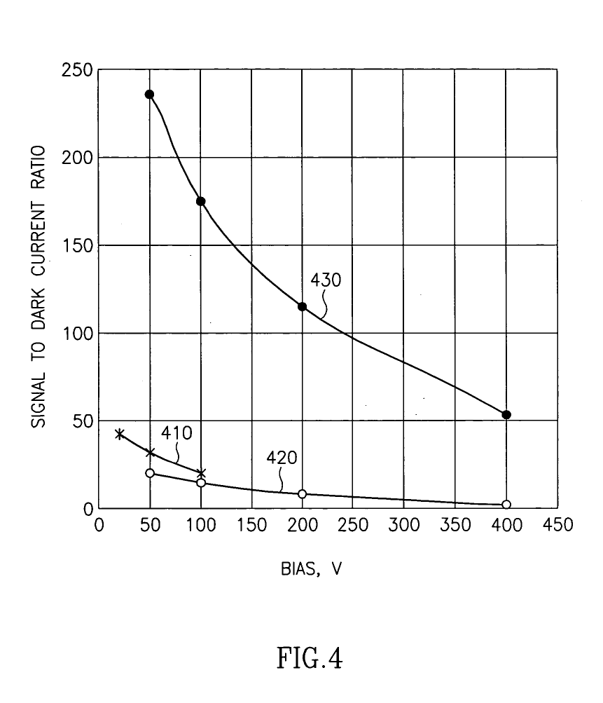

Reference is now made to FIG. 4, which is a graph showing the signal to dark current ratio vs. bias (V) response for a detector 410 including a 150 micron PVD coating layer of HgI₂, a detector 420 including a 200 micron thick composite coating layer comprising HgI₂ particles in a polymer matrix 420 and a two layer detector 430, comprising a 150 micron PVD coating layer of HgI₂ adhered with Humiseal onto a 200 micron composite coating layer comprising HgI₂ particles in a polystyrene matrix. The measurements were made using 85 kVp 50 Hz pulsed X-ray radiation with a peak flux intensity of 5 mR/sec (12 mR/pulse). FIG. 4 clearly illustrates that the two layer detector 430 has a significantly improved signal to dark current ratio vs. bias response than either the PVD detector 410 or the composite detector 420. The measurements were made with similar, sputtered gold electrodes applied to both sides of each detector layer. The composite HgI₂ in polystyrene detector 420 and the bottom film in the two layer detector 430 were fabricated by screen-printing a colloidal suspension of HgI₂ in polystyrene (PS) and toluene onto a Teflon® substrate, and subsequently evaporating off the solvent. When dry, the resulting film was peeled off and a gold electrode was sputtered onto the newly exposed surface.

Similar signal to dark current ratios may be obtained for other, less preferred, wide band gap polycrystalline semiconductor materials sometimes used in X-ray detectors, and alternative particle-matrix combinations for the dark current reducing bottom layer.

The invention will now be further illustrated by the following non-limiting Examples.

### EXAMPLE 1

### Preparation and Use of High Purity Particulate HgI₂

High purity HgI₂ was prepared in the following manner. A 0.3 M aqueous solution of HgCl₂ was slowly mixed with a 0.6 M solution of KI. The mixture was vigorously stirred using a standard mechanical stirrer and allowed to stand. HgI₂ precipitated out of solution. The precipitate was filtered, purified by repeated washing, and dried. To obtain a narrower size distribution of HgI₂ crystals, the materials was passed through commercially available sieves.

Particle in matrix composites were then formed from the HgI₂ particulate material by mixing it with a 25 wt % polystyrene in toluene solution formed by gently heating a mixture of the polymer and solvent and allowing it to cool. The HgI₂ precipitates were combined with dry polystyrene in the volume ratio of polymer semiconductor of between 1:1 and 3:7, with the mixture being thoroughly mixed to ensure uniformity of composition. The HgI₂ particle-matrix composites were used as sub-layers for polycrystalline HgI₂ films fabricated by PVD, and they successfully improved the signal to dark current ratio response thereof.

### EXAMPLE 2

### Preparation and Use of High Purity Particulate PbI₂

7.3 g of Pb(NO₃)₂ (Aldrich Chemicals, 99% pure) was added to a beaker containing 800 ml of de-ionized water, while 7.3 g of KI (Acros, 99% pure) was dissolved in a second beaker containing 200 ml of de-ionized water. Both solutions were heated to 100° C. and subsequently mixed together at that temperature. A yellow precipitate, PbI₂, in the form of thin, crystalline platelets precipitated out of the solution after the solution was cooled to room temperature and left standing for 24 hours. The precipitate was filtered and washed with 500 ml de-ionized water at room temperature for 10 minutes. After washing, the precipitate was filtered again and left to dry in air for 48 hours at room temperature. Nine grams of yellow, plate-like, PbI₂, micro-crystals were obtained.

A yellow paste was obtained by taking 5 grams of the above PbI₂ precipitate and mixing it with about 2.5 ml of 25 wt % polystyrene/toluene solution. A 400 micron thick layer of this paste was screen-printed onto an indium-tin oxide (ITO) electrode, the latter covering a glass substrate. Screen-printing was effected as described herein above. The PbI₂ layer was dried for 100 hours in air at room temperature.

Particle in matrix colloidal suspensions were then prepared from the precipitate by mixing it with a 25 wt % polystyrene in toluene solution formed by gently heating a mixture of the polymer and solvent and allowing it to cool. The PbI₂ precipitate was combined with dry polystyrene in the volume ratio of polymer: semiconductor of between 1:1 and 3:7, with the mixture being thoroughly mixed to ensure uniformity of composition.

A polymer in matrix composite layer comprising PbI₂ in polystyrene as described in Example 2 was fabricated as a dark current effects reducing substance layer. A 200 micron HgI₂ detecting layer fabricated by PVD was adhered to the PbI₂ in polystyrene composite using Humiseal. Gold electrodes were applied thereto by sputtering. The particle-matrix composite used as a sub-layer for polycrystalline HgI₂ films fabricated by PVD successfully improved the signal to dark current ratio response thereof.

### EXAMPLE 3

### Preparation and Use of High Purity Particulate BiI₃

BiI₃ powder is available commercially. 99% pure BiI₃ powder is obtainable from Aldrich Chemical Company Inc, Milwaukee USA, for example. However, a purer BiI₃ powder is obtainable by synthesis from bismuth oxynitrate (Merck®), nitric acid (HNO₃) and potassium iodide (KI) (Acros®) as follows. 20 g of KI were dissolved in 10 ml of deionized water at room temperature to form a KI solution. 150 ml of 70% HNO₃ was added to 400 ml of deionized water, and 70 g of bismuth oxynitrate were subsequently dissolved in the diluted HNO₃ solution, to form a bismuth solution. The KI solution was added to 100 ml of the bismuth solution and the resultant mixture was stirred for 2 minutes without heating. A black precipitate of BiI₃ precipitated out of solution as a result of these procedures. The BiI₃ precipitate was filtered and washed in 400 ml of 7% HNO₃ for 3 hours. After washing, the precipitate was again filtered and subsequently dried in air at room temperature for 72 hours. As a result of this procedure, 20 g of slightly agglomerated BiI₃ were obtained. The agglomerated powder was easily ground into a fine powder using a plastic spoon.

Fabrication of particle-in matrix composites therefrom was achieved by mixing 4.5 g of BiI₃ with 2 ml of 30% polystyrene in toluene solution. The resulting black paste was spread onto the surface of an ITO covered glass substrate, and compressed to a desired thickness by pressing in a die-press to form a dark current effects reducing substance layer. After drying in air for 4 days, a particle in matrix HgI₂-polystyrene (PS) composite layer similar to the one obtained in Example 1 was placed as a wide band gap semiconductor substance for detecting high energy radiation, over the BiI₃— polystyrene composite dark current effects reducing substance layer, and spread to the required thickness using the aforementioned doctor blade assembly. A gold electrode was applied thereto using sputtering.

### EXAMPLE 4

### PbI₂ and HgI₂ Double Layer Composite Detectors

Samples of composite HgI₂ and PbI₂ semiconductor particles in a polystyrene matrix were prepared according to the procedures described in Examples 1 and 2, respectively. The two composite layers were adhered to each other using a conductive double-sided adhesive sheet, and the resulting sandwich construction was electroded with gold electrodes on the sides of the layers distal from the adhesive sheet. Both positive and negative biases were applied across the sandwich construction, and good results were obtained both times. It is believed that the dominant photoconduction mechanism is holes in PbI₂ and electrons in HgI₂. This may explain the good photoconductivity obtained after reversing polarities.

Thus, multilayer X-ray detectors and imagers, and methods of manufacturing them, have been described. Specifically, multilayer wide band gap semiconductors comprising an upper electrode layer attached to a continuous wide band gap semiconductor polycrystalline upper layer, deposited onto a composite layer, or retrofitted thereto, that comprises wide band gap semiconductor particles in a polymer matrix, with a lower electrode layer attached thereto. Preferably, the lower electrode is a pixel array on a suitable substrate. Such structures exhibit reduced dark current effects and thus increased sensitivity to dark current ratio. Also disclosed are manufacturing processes suitable for assembly of such multilayer sandwich constructions.

The above discussion has generally described the semiconducting dark current effects reducing substance as being the layer positioned proximate to and deposited on a pixilated substrate, this substrate acting as an electrode. However, this is not the case in all embodiments.

Using the numbering system in FIG. 3, in some embodiments a continuous layer of a wide band semiconductor 217, typically a polycrystalline semiconductor, may be positioned near a pixelated 213 substrate 212, which serves as an electrode. In such a case, the semiconducting dark current reducing substance 215 may be deposited on the wide band semiconductor 217 and positioned distal from the pixelated 213 substrate 212 and proximate to a second electrode 218. Semiconductor layers 215 and 217, their compositions, materials and methods of preparation, are generally similar, mutatis mutandis, to those used in the embodiment shown in FIG. 3.

Layer 215 generally requires a polymer matrix. Some of the tie layers 214 and 216 may still be required as in FIG. 3. The composition and methods for forming electrode 218 would be similar to that discussed in conjunction with FIG. 3, as would the nature of the pixilated substrate. Semiconductor particle size would be similar as would the percent polymer in layer 215.

There are often advantages in using a configuration with layers 215 and 217 reversed from the way they are shown in the configuration depicted in FIG. 3. Use of such a reversed semiconductor layer configuration would be desirable when layer 217, typically a polycrystalline semiconductor, has better adhesive properties then the semiconducting dark current reducing substance 215 layer, this latter layer generally including a polymer matrix.

It should be understood that except for the reversal of layers 215 and 217, the multilayer element described in FIG. 3 and this additional embodiment are essentially similar. Accordingly, a detailed repetition of matters discussed in conjunction with FIG. 3 will not be repeated.

When the semiconducting dark current reducing substance 215 is positioned distally from the pixelated 213 substrate 212, i.e. when substrate 212 and dark current reducing substance 215 are separated by a layer of wide band gap semiconducting substance 217, the thickness of the dark current reducing substance layer 215 may be greater than when layer 215 is positioned proximately to substrate 212. When layer 215 and substrate 212 are separated by layer 217, layer 215 may range from about 10 microns to about 1000 microns, preferably between about 40 microns to about 400 microns.

### EXAMPLE 5

### Preparation and Use of High Purity Particulate Hg1₂ in Binder on PVD Layer

High purity HgI₂ was prepared in the following manner. A 0.6 M aqueous solution of HgCl₂ was slowly mixed with a 1.2 M solution of KI. The mixture was vigorously stirred using a standard mechanical stirrer and allowed to stand. HgI₂ precipitated out of solution. The precipitate was filtered, purified by repeated washing, and dried. To obtain a narrower size distribution of HgI₂ crystals, the crystals were passed through commercially available sieves.

Particle in matrix composites were then formed from the HgI₂ particulate material by mixing it with a 22 wt % polystyrene in toluene solution formed by gently heating a mixture of the polymer and solvent and allowing it to cool. The HgI₂ precipitates were combined with dry polystyrene in the volume ratio of polymer: semiconductor of between 1:1 and 3:7, with the mixture being thoroughly mixed to ensure uniformity of composition. The HgI₂ particle-matrix composites were used as a top layer for polycrystalline HgI₂ films fabricated by PVD, and they successfully improved the signal to dark current ratio response thereof.

It will be appreciated by persons skilled in the art that the present invention is not limited to what has been particularly shown and described hereinabove. Rather the scope of the present invention is defined by the appended claims and includes both combinations and sub-combinations of the various features described hereinabove as well as variations and modifications thereof that would occur to persons skilled in the art upon reading the foregoing description. In the following claims, also, the word “comprise” and its variations are to be construed in a non-limiting sense, as meaning “is composed of” at least the specified components, and does not preclude the existence of further components in the composition defined.

What is claimed is:

1. A detection and imaging system which includes at least one element enabling the detection of radiation, said element having a multilayered structure comprising a continuous first layer of a semiconducting dark current effects reducing substance, a continuous second layer of a wide band gap semiconducting substance deposited onto said first layer, a lower electrode and an upper electrode, wherein one of said continuous layers is deposited on said lower electrode and the upper electrode is deposited on the other of said continuous layers, said upper and lower electrodes thereby sandwiching said first and second continuous layers therebetween.

2. A system according to claim 1, which is further characterized by at least one of the following features:
(i) said continuous first layer of a semiconducting dark current effects reducing substance is between 10 microns and 1000 microns thick, and said continuous second layer of a wide band gap semiconducting substance is between 50 microns and 1000 microns thick;
(ii) said dark current effects reducing substance includes a particle in matrix composite, wherein (a) said particles are selected from the group consisting of cadmium zinc telluride, cadmium telluride, lead iodide, mercuric iodide, bismuth iodide, thallium bromide and mixtures thereof; and (b) said matrix material is selected from the group consisting of homopolymers and copolymers of aliphatic and aromatic monomers containing one or more ethylenic bonds;
(iii) said wide band gap semiconducting substance is a polycrystalline film deposited by vapor deposition selected from physical vapor deposition and chemical vapor deposition;
(iv) said electrodes include a material and topography and are deposited by a deposition technique, wherein said material is selected from the group consisting of indium-tin oxide, Au, Ni, Pt, Pd, Cr, Ge, Si and C, said topography is selected from the group consisting of a continuous layer, a flat panel TFT array structure, a CCD structure and a CMOS structure, and said deposition technique is selected from the group consisting of painting, spraying, sputtering, vacuum deposition and screen-printing;
(v) said system is adapted to detect and/or image electromagnetic radiation of at least about 6 KeV;
(vi) said continuous first layer of a semiconducting dark current effects reducing substance being deposited on said lower electrode and said upper electrode being deposited onto said continuous second layer of a wide band gap semiconducting substance;
(vii) said continuous second layer of a wide band gap semiconducting substance being deposited on said lower electrode and said upper electrode being deposited on said continuous first layer of a semiconducting dark current effects reducing substance
(viii) said system includes one or more tie layers, said tie layers being positioned between one of said electrodes and its proximate semiconducting layer and between said two semiconducting layers.

3. A system according to claim 2, which is further characterized by at least one of the following features:
(i) said continuous first layer of a semiconducting dark current effects reducing substance is between 40 microns and 400 microns thick, and said continuous second layer of a wide band gap semiconducting substance is between 100 microns and 400 microns thick;
(ii) at least 90% of the particles in said matrix composite are in the size range of 1 micron to 50 microns;
(iii) said vapor deposition is physical vapour deposition;
(iv) said wide band gap semiconducting substance includes HgI₂.

4. A multilayered structure for detecting electromagnetic radiation comprising a continuous first layer of a semiconducting dark current effects reducing substance, a continuous second layer of a wide band gap semiconducting substance deposited onto said first layer, a lower electrode and an upper electrode, wherein one of said continuous layers is deposited on said lower electrode and the upper electrode is deposited on the other of said continuous layers, said upper and lower electrodes thereby sandwiching said first and second continuous layers therebetween.

5. A multilayered structure according to claim 4, which is further characterized by at least one of the following features:
(i) said continuous first layer of a semiconducting dark current effects reducing substance is between 10 microns and 1000 microns thick, and said continuous second layer of a wide band gap semiconducting substance is between 50 microns and 1000 microns thick;
(ii) said dark current effects reducing substance includes a particle in matrix composite, wherein (a) said particles are selected from the group consisting of cadmium zinc telluride, cadmium telluride, lead iodide, mercuric iodide, bismuth iodide, thallium bromide and mixtures thereof; and (b) said matrix material is selected from the group consisting of homopolymers and copolymers of aliphatic and aromatic monomers containing one or more ethylenic bonds;
(iii) said wide band gap semiconducting substance is a polycrystalline film deposited by vapor deposition selected from physical vapor deposition and chemical vapor deposition;
(iv) said electrodes include a material and topography and are deposited by a deposition technique, wherein said material is selected from the group consisting of indium-tin oxide, Au, Ni, Pt, Pd, Cr, Ge, Si and C, said topography is selected from the group consisting of a continuous layer, a flat panel TFT array structure, a CCD structure and a CMOS structure, and said deposition technique is selected from the group consisting of painting, spraying, sputtering, vacuum deposition and screen-printing
(v) said continuous first layer of a semiconducting dark current effects reducing substance being deposited on said lower electrode and said upper electrode being deposited onto said continuous second layer of a wide band gap semiconducting substance
(vi) said continuous second layer of a wide band gap semiconducting substance being deposited on said lower electrode and said upper electrode being deposited on said continuous first layer of a semiconducting dark current effects reducing substance
(vii) said multilayer structure includes one or more tie layers, said tie layers being positioned between one of said electrodes and its proximate semiconducting layer and between said two semiconducting layers.

6. A multilayered structure according to claim 5, which is further characterized by at least one of the following features:
(i) said continuous first layer of a semiconducting dark current effects reducing substance is between 40 microns and 400 microns thick, and said continuous second layer of a wide band gap semiconducting substance is between 100 microns and 400 microns thick;
(ii) at least 90% of the particles in said matrix composite are in the size range of 1 micron to 50 microns;
(iii) said vapour deposition is physical vapour deposition;
(iv) said wide band gap semiconducting substance includes HgI₂.

7. A detection and imaging system which includes at least one element enabling the detection of radiation, said element having a multilayered structure comprising a lower electrode, a continuous first layer of a semiconducting dark current effects reducing substance deposited thereon, a continuous second layer of a wide band gap semiconducting substance deposited onto said first layer, and an upper electrode deposited onto said second.

8. A system according to claim 7, which is further characterized by at least one of the following features:
(i) said continuous first layer of a semiconducting dark current effects reducing substance is between 10 microns and 400 microns thick, and said continuous second layer of a wide band gap semiconducting substance is between 50 microns and 1000 microns thick;
(ii) said dark current effects reducing substance includes a particle in matrix composite, wherein (a) said particles are selected from the group consisting of cadmium zinc telluride, cadmium telluride, lead iodide, mercuric iodide, bismuth iodide, thallium bromide and mixtures thereof; and (b) said matrix material is selected from the group consisting of homopolymers and copolymers of aliphatic and aromatic monomers containing one or more ethylenic bonds;
(iii) said wide band gap semiconducting substance is a polycrystalline film deposited by vapor deposition selected from physical vapor deposition and chemical vapor deposition;
(iv) said electrodes include a material and topography and are deposited by a deposition technique, wherein said material is selected from the group consisting of indium-tin oxide, Au, Ni, Pt, Pd, Cr, Ge, Si and C, said topography is selected from the group consisting of a continuous layer, a flat panel TFT array structure, a CCD structure and a CMOS structure, and said deposition technique is selected from the group consisting of painting, spraying, sputtering, vacuum deposition and screen-printing;
(v) said system is adapted to detect and/or image electromagnetic radiation of at least about 6 KeV
(vi) said system includes one or more tie layers, said tie layers being positioned between one of said electrodes and its proximate semiconducting layer and between said two semiconducting layers.

9. A system according to claim 8, which is further characterized by at least one of the following features:
(i) said continuous first layer of a semiconducting dark current effects reducing substance is between 40 microns and 200 microns thick, and said continuous second layer of a wide band gap semiconducting substance is between 100 microns and 400 microns thick;
(ii) at least 90% of the particles in said matrix composite are in the size range of 1 micron to 50 microns;
(iii) said vapor deposition is physical vapour deposition;
(iv) said wide band gap semiconducting substance includes HgI₂.

10. A multilayered structure for detecting electromagnetic radiation comprising a lower electrode, a continuous first layer of a semiconducting dark current effects reducing substance deposited thereon, a continuous second layer of a wide band gap semiconducting substance deposited onto said first layer, and an upper electrode deposited onto said second layer.

11. A multilayered structure according to claim 10, which is further characterized by at least one of the following features:
(i) said continuous first layer of a semiconducting dark current effects reducing substance is between 10 microns and 400 microns thick, and said continuous second layer of a wide band gap semiconducting substance is between 50 microns and 1000 microns thick;
(ii) said dark current effects reducing substance includes a particle in matrix composite, wherein (a) said particles are selected from the group consisting of cadmium zinc telluride, cadmium telluride, lead iodide, mercuric iodide, bismuth iodide, thallium bromide and mixtures thereof; and (b) said matrix material is selected from the group consisting of homopolymers and copolymers of aliphatic and aromatic monomers containing one or more ethylenic bonds;
(iii) said wide band gap semiconducting substance is a polycrystalline film deposited by vapor deposition selected from physical vapor deposition and chemical vapor deposition;
(iv) said electrodes include a material and topography and are deposited by a deposition technique, wherein said material is selected from the group consisting of indium-tin oxide, Au, Ni, Pt, Pd, Cr, Ge, Si and C, said topography is selected from the group consisting of a continuous layer, a flat panel TFT array structure, a CCD structure and a CMOS structure, and said deposition technique is selected from the group consisting of painting, spraying, sputtering, vacuum deposition and screen-printing
(v) said multilayer structure includes one or more tie layers, said tie layers being positioned between one of said electrodes and its proximate semiconducting layer and between said two semiconducting layers.

12. A multilayered structure according to claim 11, which is further characterized by at least one of the following features:
(i) said continuous first layer of a semiconducting dark current effects reducing substance is between 40 microns and 200 microns thick, and said continuous second layer of a wide band gap semiconducting substance is between 100 microns and 400 microns thick;
(ii) at least 90% of the particles in said matrix composite are in the size range of 1 micron to 50 microns;
(iii) said vapour deposition is physical vapour deposition;
(iv) said wide band gap semiconducting substance includes HgI₂.
